(19) United States
(12) Patent Application Publication
(10) Pub. No.: US 2026/0205082 A1
(43) Pub. Date: Jul. 16, 2026

(54) TRANSCONDUCTANCE GAIN CALIBRATION CIRCUIT

(71) Applicant: REALTEK SEMICONDUCTOR CORP., Hsinchu (TW)

(72) Inventors: Sie-Siou Jhang Jian, Hsinchu (TW); Chih-Lung Chen, Hsinchu (TW)

(73) Assignee: REALTEK SEMICONDUCTOR CORP., Hsinchu (TW)

(21) Appl. No.: 19/447,734

(22) Filed: Jan. 13, 2026

(30) Foreign Application Priority Data
Jan. 14, 2025 (TW) 114101547

(51) Int. Cl. H03G 3/30; H03F 1/30; H03F 3/45

(52) U.S. Cl. CPC H03G 3/30; H03F 1/303; H03F 3/45475

(57) ABSTRACT

A transconductance gain calibration circuit includes a constant voltage source, a first transconductance amplifier, a second transconductance amplifier, and a comparison module. The constant voltage source is configured to generate a reference voltage. The first transconductance amplifier responds to the reference voltage to produce a constant current. The second transconductance amplifier responds to the reference voltage to produce a variation current. The comparison module includes a first potentiometer, a reference resistor, and a comparison circuit. The first potentiometer is coupled to the first transconductance amplifier and is configured to generate a variation voltage based on the constant current and an adjustable resistance. The reference resistor is coupled to the second transconductance amplifier and is configured to generate a constant voltage based on the variation current and a designed resistance value. The comparison circuit is configured to compare the variation voltage with the constant voltage to adjust the adjustable resistance.

### CROSS-REFERENCE TO RELATED APPLICATION

This non-provisional application claims priority under 35 U.S.C. § 119(a) to Patent Application No. 114101547 filed in Taiwan, R.O.C. on January 14, 2025, the entire contents of which are hereby incorporated by reference.

### BACKGROUND

### Technical Field

The present disclosure is a parameter calibration circuit, and in particular to a parameter calibration circuit suitable for calibrating transconductance gain.

### Related Art

Constant gm circuits provide stable transconductance (i.e., gm) to maintain stable system gain and bandwidth in a variety of applications, such as TX Bias, Low-Noise Amplifier (LNA), and Gm-C filters to maintain a stable cut-off frequency. The constancy of the transconductance of the constant gm circuits depends on parameter conditions in the circuits, for example, a bias resistor with designed resistance value of R in the system, so that gm*R is a constant constant, and is not affected by changes in parameters such as process, voltage, and temperature (i.e., PVT).

In general, a precision off-chip resistor can be combined with the constant gm circuits to provide a constant transconductance, however, this not only increases the cost of the system, but also increases the complexity of the off-chip resistor selection and test operation.

### SUMMARY

In view of this, the applicant provides a transconductance gain calibration circuit, including a constant voltage source, a first transconductance amplifier, a second transconductance amplifier, and a comparison module. The constant voltage source is configured to generate a reference voltage. The first transconductance amplifier responds to the reference voltage to produce a constant current. The second transconductance amplifier responds to the reference voltage to produce a variation current. The comparison module includes a first potentiometer, a reference resistor, and a comparison circuit. The first potentiometer is coupled to the first transconductance amplifier, has an adjustable resistance, and is configured to generate a variation voltage based on the constant current and the adjustable resistance. The reference resistor is coupled to the second transconductance amplifier, has a designed resistance value, and is configured to generate a constant voltage based on the variation current and the designed resistance value. The comparison circuit is configured to compare the variation voltage with the constant voltage to adjust the adjustable resistance.

### BRIEF DESCRIPTION OF THE DRAWINGS

FIG. 1 is a circuit diagram of a constant gm circuit according to some embodiments.

FIG. 2 is a block diagram of a transconductance gain calibration circuit according to some embodiments.

FIG. 3 is a circuit diagram of a transconductance amplifier according to some embodiments.

FIG. 4 is a circuit diagram of a comparison module according to some embodiments.

FIG. 5 is a circuit diagram of a first potentiometer according to some embodiments.

### DETAILED DESCRIPTION

The terms "one" or "a kind of" used in this text refer to elements and components of this creation. The terms are for the convenience of description and provide a basic concept of this creation. This description shall be understood to include one or at least one, and unless it is clearly stated otherwise, to include the singular as well as the plurality. When used in conjunction with the word "include" or "comprise" in the scope of the patent application, the term "one" may mean one or more than one.

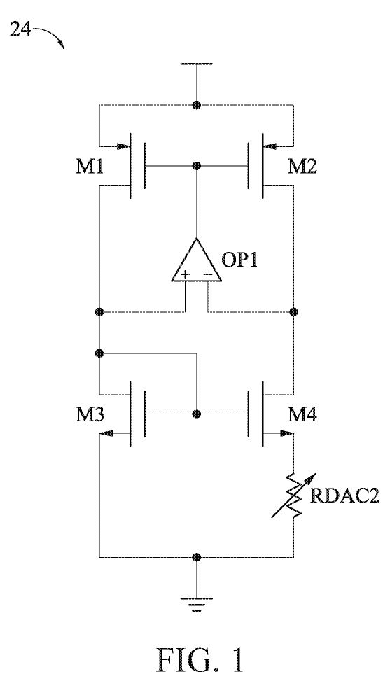

FIG. 1 is a circuit diagram of a constant gm circuit according to some embodiments, please refer to FIG. 1. In the embodiment, a constant gm circuit 24 is based on a current mirror architecture, a reference current side includes a transistor M3, and an output current side of a mirror image includes a transistor M4. A transistor M1 and a transistor M2 are configured to provide balanced output of differential current, and an operational amplifier OP1 detects the voltage difference between the transistor M3 and the transistor M4, and controls working points of the transistor M1 and the transistor M2 by way of output feedback, so as to generate a stable output current. A second potentiometer RDAC2 is arranged between a source electrode of the transistor M4 and a grounding end, a resistance R of the second potentiometer RDAC2 can be adjusted; and the product of the transconductance (gm) of the constant gm circuit 24 and the resistance R of the second potentiometer RDAC2 is a constant, namely, gm*R=k, and k is a constant. When the resistance R of the second potentiometer RDAC2 decreases, the gm of the constant gm circuit 24 increases. Therefore, the second potentiometer RDAC2 is configured to adjust the gm of the constant gm circuit 24 to meet the acceptance standard of designed transconductance.

The designed transconductance may refer to a transconductance defined according to circuit parameters applied by the constant gm circuit 24. For example, the designed transconductance is specified according to a specific cut-off frequency requirement of a Gm-C filter. Generally, the second potentiometer RDAC2 may be influenced by PVT parameters to cause variation in the resistance, resulting in variation of an actual transconductance of the constant gm circuit 24 and deviating from the designed transconductance. Therefore, in some embodiments, a transconductance gain calibration circuit 20 needs to calibrate the second potentiometer RDAC2 to make the constant gm circuit 24 reach the designed transconductance. In some embodiments, the second potentiometer RDAC2 is a digital potentiometer, so the resistance will be adjusted according to code setting. In other embodiments, the constant gm circuit 24 can adopt the second potentiometer RDAC2 on the basis of the known configuration of the constant gm circuit and bias resistance of the constant gm circuit, so that the product of gm*resistance R is a constant.

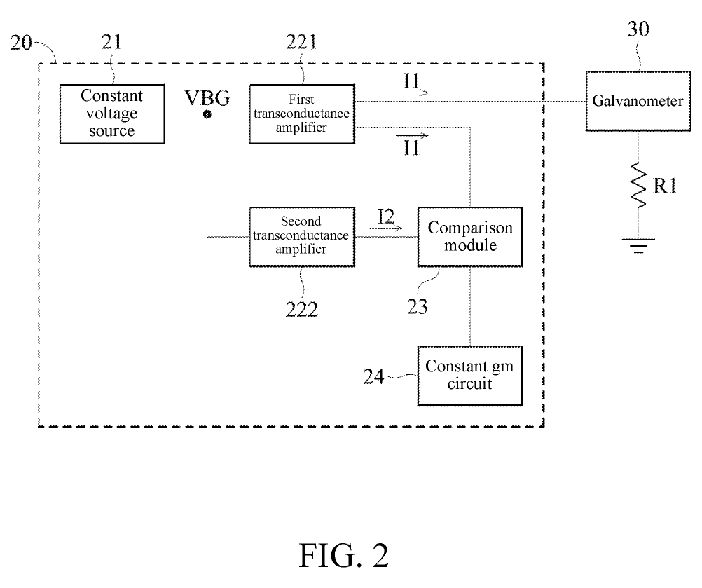

FIG. 2 is a block diagram of a transconductance gain calibration circuit according to some embodiments, please refer to FIG. 2. In the embodiment, the transconductance gain calibration circuit 20 includes a constant voltage source 21, a first transconductance amplifier 221, a second transconductance amplifier 222, a comparison module 23 and the constant gm circuit 24. The constant voltage source 21 is electrically connected to the first transconductance amplifier 221 and the second transconductance amplifier 222, the first transconductance amplifier 221 is electrically connected to the comparison module 23, and the second transconductance amplifier 222 is also electrically connected to the comparison module 23. The comparison module 23 is electrically connected to the constant gm circuit 24. In other embodiments, the transconductance gain calibration circuit 20 only includes the constant voltage source 21, the first transconductance amplifier 221, the second transconductance amplifier 222 and the comparison module 23, and the comparison module 23 can be electrically connected to the off-chip constant gm circuit 24. In the embodiment, the constant voltage source 21 is configured to generate a reference voltage VBG, the first transconductance amplifier 221 receives the reference voltage VBG and generates a constant current I1, and the constant current I1 is outputted to the comparison module 23; and the second transconductance amplifier 222 receives the reference voltage VBG and generates a variation current I2, and the variation current I2 is outputted to the comparison module 23.

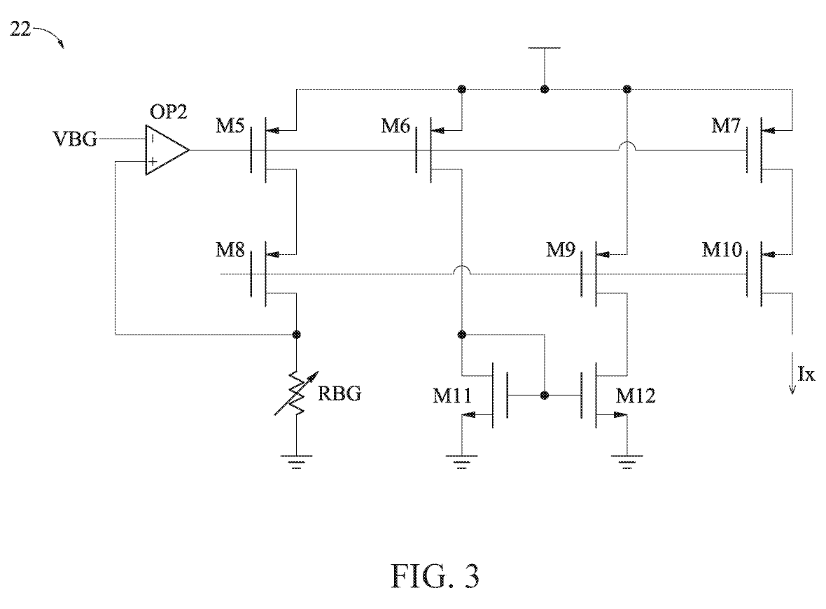

The constant voltage source 21 can be configured to generate a constant reference voltage VBG, namely a constant reference voltage VBG that is not influenced by the PVT parameters. For example, the constant voltage source 21 can adopt a bandgap reference (BGR) circuit which can be configured into a combination of a positive-temperature-coefficient voltage source and a negative-temperature-coefficient voltage source. A transconductance amplifier 22 (the first transconductance amplifier 221 or the second transconductance amplifier 222) , which can be on the basis of a circuit configuration of a voltage-current converter (VtoI Converter), generates an output current Ix according to the reference voltage VBG. FIG. 3 is a circuit diagram of a transconductance amplifier according to some embodiments, please refer to FIG. 3. In the embodiment, the transconductance amplifier 22 is based on a current mirror architecture, and a reference current side includes a voltage-current conversion circuit. The conversion circuit includes an operational amplifier OP2, a transistor M5 and a transistor M8. A third potentiometer RBG is coupled between an output end of the transistor M8 and a grounding end. The conversion circuit is configured to generate a reference current, and the reference current generates a bias voltage at the output end (drain electrode) of the transistor M8 by way of the third potentiometer RBG and feeds back to the operational amplifier OP2. An output end of the operational amplifier OP2 is coupled to an input end (gate electrode) of the transistor M5, and the operational amplifier OP2 changes an output value based on the reference voltage VBG and the feedback bias voltage, and adjusts a working point of the transistor M5 so as to generate a stable reference current.

In the embodiment, a reference current side of a current mirror circuit of the transconductance amplifier 22 includes a transistor M6 and a transistor M11. The output end of the operational amplifier OP2 is coupled to an input end (gate electrode) of the transistor M6 to adjust a working point of the transistor M6, so that a mirror current flowing through the transistor M6 and the transistor M11 is produced, and the magnitude of the mirror current is substantially equal to that of the reference current flowing through the transistor M5 and the transistor M8. In addition, the mirror current flows through a current mirror, and a transistor M9 and a transistor M12 at the output side and a transistor M7 and a transistor M10 form the mirror current respectively, so that an output current Ix is generated. The reference current is changed by adjusting a resistance of the third potentiometer RBG, and then the magnitude of the output current Ix can be further changed. In some embodiments, the third potentiometer RBG is a digital potentiometer, so the resistance is adjusted according to code setting. As shown in FIG. 3, in some embodiments, the current mirror circuit may include a plurality of groups of output sides for generating the mirror output current Ix respectively. For example, the first transconductance amplifier 221 in FIG. 2 includes at least two groups of output sides, one group of output sides is coupled to an off-chip circuit, and the other group of output sides is coupled to the comparison module 23.

Please refer to FIG. 2 and FIG. 3, in the embodiment, the output side (drain electrode end of the transistor M10) of the current mirror circuit of the transconductance amplifier 22 is coupled to an off-chip galvanometer 30. As shown in FIG. 2, the first transconductance amplifier 221 is connected to the galvanometer 30 and a load R1 in series, and the galvanometer 30 is configured to measure a measured value of the output current Ix. The deviation between the measured value and a designed current value can be used for calibrating the resistance of the third potentiometer RBG, so that the output current Ix of the first transconductance amplifier 221 is equal to the designed current value. The designed current value can refer to a current value defined by the transconductance amplifier 22 according to calibration parameters. In some embodiments, the designed current value is equivalent to a product of the reference voltage VBG and the designed transconductance. In the embodiment, the first transconductance amplifier 221 is based on the constant reference voltage VBG and is calibrated by the galvanometer 30, so the output current Ix is a constant current I1, namely a current that is not influenced by the PVT parameters; and the second transconductance amplifier 222 is not calibrated by the galvanometer 30, so the output current Ix is a variation current I2, namely a current that may be influenced by the PVT parameters. However, the voltage reference of the second transconductance amplifier 222 is not influenced by off-chip calibration, so the output voltage thereof maintains the same characteristics as the reference voltage VBG, namely a voltage that is not influenced by the PVT parameters. In some embodiments, the first transconductance amplifier 221 and the second transconductance amplifier 222 have the same configuration, such as the transconductance amplifier 22 shown in FIG. 3; and based on this, the parameter difference between the first transconductance amplifier 221 and the second transconductance amplifier 222 only depends on the difference in calibration, such as the resistance of the third potentiometer RBG.

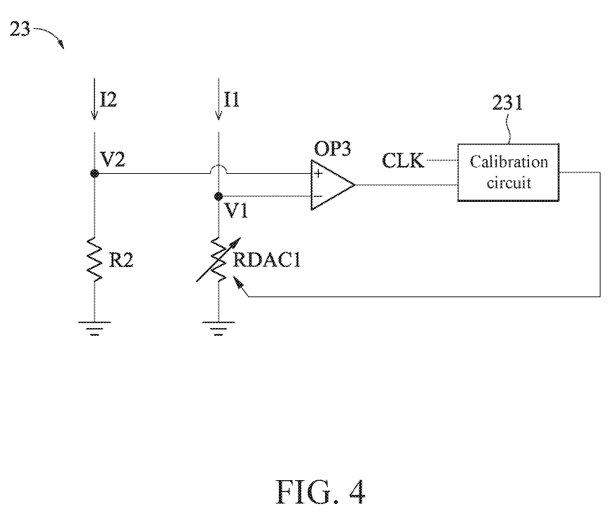

FIG. 4 is a circuit diagram of a comparison module according to some embodiments, please refer to FIG. 2 and FIG. 4. In the embodiment, the comparison module 23 includes a first potentiometer RDAC1, a reference resistor R2 and a comparison circuit. The first potentiometer RDAC1 is coupled to the first transconductance amplifier 221 to receive the constant current I1. The first potentiometer RDAC1 is arranged between the first transconductance amplifier 221 and the grounding end, and the resistance r of the first potentiometer RDAC1 can be adjusted. The resistance r of the first potentiometer RDAC1 is not a constant value due to the influence of the PVT parameters, and therefore it needs to be calibrated. The constant current I1 forms a bias voltage, namely a variation voltage V1, by way of the first potentiometer RDAC1. The variation voltage V1 is also influenced by the PVT parameters due to the influence of the resistance r. The reference resistor R2 is coupled to the second transconductance amplifier 222 to receive a variation current I2. The reference resistor R2 is arranged between the second transconductance amplifier 222 and the grounding end, and the variation current I2 forms a bias voltage, namely a constant voltage V2, by way of the reference resistor R2. As described above, the voltage reference of the second transconductance amplifier 222 is not influenced by off-chip calibration, so the output voltage (namely the constant voltage V2) of the second transconductance amplifier 222 is not influenced by the PVT parameters. In some embodiments, the reference resistor R2 has a designed resistance value, and the designed resistance value and the designed transconductance are reciprocal. Therefore, the designed resistance value of the reference resistor R2 is defined by circuit parameters applied by the constant gm circuit 24. The designed resistance value is used for calibrating the constant gm circuit 24 to meet the acceptance standard of the designed transconductance.

The comparison circuit is configured to compare the variation voltage V1 with the constant voltage V2 so as to adjust the resistance r of the first potentiometer RDAC1. As shown in FIG. 4, in the embodiment, the comparison circuit includes a comparator OP3 and a calibration circuit 231, and the calibration circuit 231 is configured to adjust the resistance r of the first potentiometer RDAC1 so as to adjust the variation voltage V1. An input end of the comparator OP3 is coupled to the first potentiometer RDAC1 and the reference resistor R2 to receive the variation voltage V1 and the constant voltage V2 for comparison and to feed back a comparison result to the calibration circuit 231. Therefore, in the embodiment, when the calibration circuit 231 judges that the variation voltage V1 is greater than the constant voltage V2 (corresponding to a logic value 1), the resistance r is turned down; and when the calibration circuit 231 judges that the variation voltage V1 is smaller than the constant voltage V2 (corresponding to a logic value 0), the resistance R is turned up. As described above, the variation voltage V1 is the product of the resistance r and the constant current I1, and the PVT variation of the variation voltage V1 is only on the basis of the resistance r. Therefore, the comparator OP3 calibrates the resistance r of the first potentiometer RDAC1 with the constant voltage V2 as a PVT constant reference. In some embodiments, the first potentiometer RDAC1 is a digital potentiometer, so the resistance is adjusted according to coding setting.

In the embodiment, the calibration circuit 231 receives a clock input CLK and is triggered by a clock to periodically calibrate the first potentiometer RDAC1. The clock input CLK can be from an off-chip clock signal source of the transconductance gain calibration circuit 20. The calibration circuit 231 may include a digital logic, so the first potentiometer RDAC1 is adjusted according to a logic value outputted by the comparator OP3, for example, a coded value of the first potentiometer RDAC1 is set. The calibration circuit 231 can be but not limited to an application specific integrated circuit (ASIC), a field programmable gate array (FPGA), a programmable logic device (PLD) or a field-programmable analog array (FPAA).

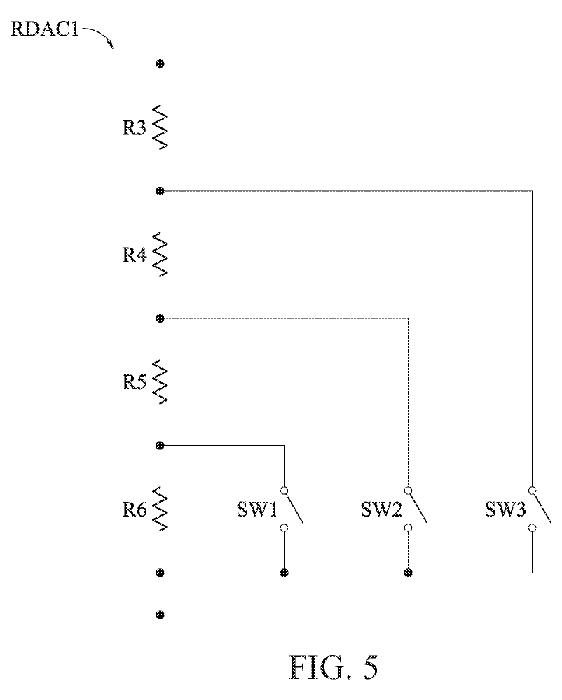

FIG. 5 is a circuit diagram of a first potentiometer according to some embodiments, please refer to FIG. 4 and FIG. 5. In the embodiment, the first potentiometer RDAC1 includes a divider resistor R3, a divider resistor R4, a divider resistor R5, a divider resistor R6, a first switch SW1, a second switch SW2 and a third switch SW3. The divider resistor R3, the divider resistor R4, the divider resistor R5 and the divider resistor R6 are connected in series, the first switch SW1 is bridged to the divider resistor R6, the second switch SW2 is bridged to the divider resistor R5 and the divider resistor R6, and the third switch SW3 is bridged to the divider resistor R4, the divider resistor R5 and the divider resistor R6. In the embodiment, a node at an upper end of the divider resistor R3 serves as the input/output end of the first potentiometer RDAC1, and a node at a lower end of the divider resistor R6 serves as the output/input end of the first potentiometer RDAC1. In the embodiment, the calibration circuit 231 is respectively coupled to the first switch SW1, the second switch SW2 and the third switch SW3 so as to respectively control an on-off state. For the first potentiometer RDAC1, when a number of the divider resistors is N, the number of the switches will be N-1, one end of each switch is connected to the input/output end of the first potentiometer RDAC1, and the other end of each switch is connected among the nodes between the divider resistors. In the embodiment, N is 4, but not limited to this. In other embodiments, N is a numerical value greater than or equal to 3.

In the embodiment, the on-off states of the first switch SW1, the second switch SW2 and the third switch SW3 can be represented as 1 (off) and 0 (on). Therefore, the on-off state of the first potentiometer RDAC1 in FIG. 5 is represented as [0,0,0], namely the first switch SW1 is on, the second switch SW2 is on, and the third switch SW3 is on, and the resistance r is the sum of the resistance of the divider resistor R3, the divider resistor R4, the divider resistor R5 and the divider resistor R6. Therefore, the on-off state of the first potentiometer RDAC1 can include [0,0,0], [1,0,0], [1,1,0], and [1,1,1], and the resistance r sequentially corresponds to the sum of the resistance of (R3+R4+R5+R6), (R3+R4+R5), (R3+R4) and R3, four resistances in total. Therefore, the on-off state can be represented by two-bit codes sequentially corresponding to (0,0), (0,1), (1,0) and (1,1). The number of the code bits is related to the N value of the first potentiometer RDAC1, and when the number of the code bits is smaller, the calibration speed of the transconductance gain calibration circuit 20 is higher, and thus a clock input CLK with higher frequency can be adopted; and when the number of the code bits is larger, the calibration precision of the transconductance gain calibration circuit 20 on the transconductance is higher.

In some embodiments, the calibration circuit 231 responds to that the variation voltage V1 is greater than the constant voltage V2 to sequentially turn off the first switch SW1, the second switch SW2 and the third switch SW3. In detail, please refer to FIG. 4 and FIG. 5, in a first clock cycle, the on-off state of the first potentiometer RDAC1 is [0,0,0], and the first potentiometer RDAC1 has a resistance r4, namely the sum of resistance of (R3+R4+R5+R6). The variation voltage V1 is the product of the constant current I1 and the resistance r4. When the comparator OP3 judges that the variation voltage V1 is greater than the constant voltage V2, the first switch SW1 is controlled to be off. At the moment, the resistance r4 of the first potentiometer RDAC1 decreases to the resistance r3. In a second clock cycle, the on-off state of the first potentiometer RDAC1 is [1,0,0], and the first potentiometer RDAC1 has the resistance r3, namely the sum of resistance of (R3+R4+R5). The variation voltage V1 is the product of the constant current I1 and the resistance r3. When the comparator OP3 judges that the variation voltage V1 is greater than the constant voltage V2, the second switch SW2 is controlled to be off. At the moment, the resistance r3 of the first potentiometer RDAC1 decreases to the resistance r2. In a third clock cycle, the on-off state of the first potentiometer RDAC1 is [1,1,0], and the first potentiometer RDAC1 has the resistance r2, namely the sum of resistance of (R3+R4). The variation voltage V1 is the product of the constant current I1 and the resistance r2. When the comparator OP3 judges that the variation voltage V1 is smaller than the constant voltage V2, the calibration of the first potentiometer RDAC1 is completed. At the moment, the code of the first potentiometer RDAC1 is [1,0], and the resistance r2 is a calibrated resistance.

In some other embodiments, the calibration circuit 231 responds to that the constant voltage V2 is greater than the variation voltage V1 to sequentially turn on the third switch SW3, the second switch SW2 and the first switch SW1. In detail, in a first clock cycle, the on-off state of the first potentiometer RDAC1 is [1,1,1], and the first potentiometer RDAC1 has a resistance r1, namely the resistance of R3. The variation voltage V1 is the product of the constant current I1 and the resistance r1. When the comparator OP3 judges that the constant voltage V2 is greater than the variation voltage V1, the third switch SW3 is controlled to be on. At the moment, the resistance r1 of the first potentiometer RDAC1 increases to the resistance r2. In a second clock cycle, the on-off state of the first potentiometer RDAC1 is [1,1,0], and the first potentiometer RDAC1 has a resistance r2, namely the sum of the resistance of (R3+R4). The variation voltage V1 is the product of the constant current I1 and the resistance r2. When the comparator OP3 judges that the constant voltage V2 is smaller than the variation voltage V1, the calibration of the first potentiometer RDAC1 is completed. At the moment, the code of the first potentiometer RDAC1 is [1,0], and the resistance r2 is a calibrated resistance. Based on the above, in some embodiments, the comparison module 23 sequentially turns on/off each switch according to the code, and the sequence is determined according to the coding sequence of the first potentiometer RDAC1; or, the sequence is determined according to the number of divider resistors bridged by the switches; or, the sequence is determined according to the resistor state of the first potentiometer RDAC1. In some embodiments, when the calibration circuit 231 judges that the output logic value of the comparator OP3 changes, the calibration program is ended.

In some embodiments, the transconductance gain calibration circuit 20 includes the constant voltage source 21, the first transconductance amplifier 221, the second transconductance amplifier 222 and the comparison module 23, and the transconductance gain calibration circuit 20 is configured to calibrate the off-chip constant gm circuit 24. The comparison module 23 generates a resistance control signal and outputs the resistance control signal to the constant gm circuit 24 so as to control the second potentiometer RDAC2 of the constant gm circuit 24. In the embodiment, please refer to FIG. 2, the transconductance gain calibration circuit 20 includes the constant voltage source 21, the first transconductance amplifier 221, the second transconductance amplifier 222, the comparison module 23 and the constant gm circuit 24, and the comparison module 23 is coupled to the second potentiometer RDAC2 of the constant gm circuit 24 and adjusts the resistance of the second potentiometer RDAC2 according to the resistance control signal to make the resistance of the second potentiometer RDAC2 to be identical to that of the first potentiometer RDAC1. In some embodiments, the ambient temperature simultaneously affects the first potentiometer RDAC1 and the second potentiometer RDAC2 to cause resistance offset, and the transconductance gain calibration circuit 20 calibrates the resistance of the first potentiometer RDAC1 and controls the resistance of the second potentiometer RDAC2 to be identical to that of the first potentiometer RDAC1, thus achieving calibration of the constant gm circuit 24. In some embodiments, the temperature coefficient of the reference resistor R2 and the temperature coefficient of the first potentiometer RDAC1 are in a positive correlation, and when the ambient temperature simultaneously affects the reference resistor R2 and the first potentiometer RDAC1, the reference resistor R2 and the first potentiometer RDAC1 are subjected to resistance offset in the same trend, so that the comparator OP3 can still calibrate the first potentiometer RDAC1 according to the voltage difference between the variation voltage V1 and the constant voltage V2.

In some embodiments, the first potentiometer RDAC1 and the second potentiometer RDAC2 have the same design specification, so that the resistance offsets of the first potentiometer RDAC1 and the second potentiometer RDAC2 in response to the PVT variation are substantially the same. The same design specifications can refer to the same type number, or the same manufacturer, or the same batch number, or the same production sequence number. According to the embodiment, the comparison module 23 completes the coded value setting of the first potentiometer RDAC1 and outputs a resistance control signal including the coded value to the second potentiometer RDAC2, so that the second potentiometer RDAC2 and the first potentiometer RDAC1 have the same on-off state.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A transconductance calibration circuit, comprising:
a constant voltage source configured to generate a reference voltage;
a first transconductance amplifier responding to the reference voltage to produce a constant current;
a second transconductance amplifier responding to the reference voltage to produce a variation current; and
a comparison module, comprising:
a first potentiometer coupled to the first transconductance amplifier, having an adjustable resistance, and configured to generate a variation voltage based on the constant current and the adjustable resistance;
a reference resistor coupled to the second transconductance amplifier, having a designed resistance value, and configured to generate a constant voltage based on the variation current and the designed resistance value; and
a comparison circuit configured to compare the variation voltage with the constant voltage to adjust the adjustable resistance.

2. The transconductance calibration circuit according to claim 1, further comprising a constant gm circuit comprising a second potentiometer configured to adjust the constant gm circuit to reach a designed transconductance, wherein the comparison module is configured to set a resistance of the second potentiometer as the adjustable resistance.

3. The transconductance calibration circuit according to claim 2, wherein the first potentiometer and the second potentiometer have a same design specification.

4. The transconductance calibration circuit according to claim 2, wherein the designed resistance value and the designed transconductance are reciprocal.

5. The transconductance calibration circuit according to claim 1, wherein the constant voltage source is a bandgap reference circuit.

6. The transconductance calibration circuit according to claim 1, wherein the first transconductance amplifier and the second transconductance amplifier have a same configuration, each comprising a current mirror circuit; a reference current side of the current mirror circuit receives the reference voltage and generates a reference current according to a third potentiometer; and an output side of the current mirror circuit of the first transconductance amplifier is suitable for coupling to an off-chip galvanometer, which is configured to calibrate a resistance of the third potentiometer, and makes the first transconductance amplifier outputs the constant current.

7. The transconductance calibration circuit according to claim 6, wherein the reference current side of the current mirror circuit further comprises a conversion circuit; the conversion circuit comprises an operational amplifier and a transistor circuit; an output end of the transistor circuit is coupled to a positive end of the operational amplifier, and the constant voltage source is coupled to a negative end of the operational amplifier; an output end of the operational amplifier is coupled to an input end of the transistor circuit; and the third potentiometer is coupled between the output end of the transistor circuit and a grounding end.

8. The transconductance calibration circuit according to claim 1, wherein the comparison circuit comprises a comparator and a calibration circuit; a pair of input ends of the comparator respectively receives the variation voltage and the constant voltage; the calibration circuit is coupled to an output end of the comparator; and when the calibration circuit judges that the variation voltage is greater than the constant voltage, the adjustable resistance is turned down.

9. The transconductance calibration circuit according to claim 1, wherein the first potentiometer is a digital potentiometer and comprises a first switch, a second switch, a first resistor, a second resistor and a third resistor; the first resistor, the second resistor and the third resistor are connected in series; the first switch is bridged to the third resistor; the second switch is bridged to the second resistor and the third resistor; and the comparison module responds to that the variation voltage is greater than the constant voltage to sequentially turn off the first switch and the second switch.

10. The transconductance calibration circuit according to claim 1, wherein the first potentiometer is a digital potentiometer and comprises a first switch, a second switch, a first resistor, a second resistor and a third resistor; the first resistor, the second resistor and the third resistor are connected in series; the first switch is bridged to the third resistor; the second switch is bridged to the second resistor and the third resistor; and the comparison module responds to that the constant voltage is greater than the variation voltage to sequentially turn on the second switch and the first switch.
